(19) United States
(12) Patent Application Publication
(10) Pub. No.: US 2013/0101251 A1
(43) Pub. Date: Apr. 25, 2013

(54) Optical Module and Multilayer Substrate

(71) Applicant: Hitachi, Ltd., Tokyo (JP)

(72) Inventors: Daichi KAWAMURA, Mito (JP); Kenji Kogo, Koganei (JP); Yasunobu Matsuoka, Hachioji (JP); Toshiki Sugawara, Kokubunji (JP)

(21) Appl. No.: 13/658,406

(22) Filed: Oct. 23, 2012

(30) Foreign Application Priority Data
Oct. 24, 2011 (JP) 2011-232611

(51) Int. Cl. G02B 6/12; H05K 1/11

(52) U.S. Cl. CPC G02B 6/12; H05K 1/113
USPC 385/14; 174/266

(57) ABSTRACT

In first and second electrode pads adjacent to each other formed over a multilayer substrate, the first electrode pad is connected with a first conductive via and a first internal layer conductive line successively. The second electrode pad is connected with a surface layer conductive line, third electrode pad, second conductive via, and second internal layer conductive line of the multilayer substrate. A ground conductive via or a power source conductive via is disposed between the first internal layer conductive line and the surface layer conductive line. A ground conductive line layer or power source conductive line layer is disposed between a first formation layer where the first internal layer conductive line is formed and a second formation layer where the second internal layer conductive line is formed. The first and second electrode pads are connected with the electrode pads formed on the surface of first and second optical devices.

### CLAIM OF PRIORITY

The present application claims priority from Japanese patent application JP 2011-232611 filed on Oct. 24, 2011, the content of which is hereby incorporated by reference into this application.

### FIELD OF THE INVENTION

The present invention concerns an optical module using a multilayer substrate for use in optical communication. Particularly, it relates to a technique useful for an optical module intended for super high speed operation at 25 Gbps or higher.

### BACKGROUND OF THE INVENTION

Along with rapid popularization of internets, increase in the operation speed and the capacity of IT apparatus typically represented by router-servers has been progressed rapidly. At present, a board provided with electric interconnects, electronic parts mounted over the board and, further, electric transmission lines for coupling electronic parts are mounted in such apparatus. That is, most of data inputted from the outside of the apparatus are processed as electric signals in the apparatus.

However, the amount of information to be processed and the processing speed thereof per one apparatus have been increased year and year, the density of electric interconnects in the apparatus has been increased and the frequency of signals used therefor has become higher, and transmission loss in the electric interconnects and crosstalk between adjacent signal interconnects have become conspicuous. In recent years, apparatus of coupling electronic components to each other by optical signals have been developed vigorously in order to overcome the drawbacks of the electric interconnects described above. Since light is non-inductive, the apparatus has an advantage of not generating transmission loss and crosstalk even when the transmission rate of optical signals increases. As a conventional semiconductor device for transmitting signals between electronic parts by optical signals, an optical module in which optical devices and an integrated circuit are mounted on the surface and the optical devices and the integrated circuit are electrically connected by wire bonding has been known, for example, in Japanese Unexamined Patent Application Publication No. 2010-177593, etc.

In FIG. 1, the optical device is a semiconductor laser of converting electric signals into optical signals and a photodiode of converting the optical signals into electric signals and the integrated circuit is a driver circuit for shaping and amplifying electric signals in the stage preceding the semiconductor laser, or a transimpedance amplifier circuit of converting electric signals (current signals) outputted from the photodiode into voltage signals and then amplifying the voltage signals. For multi-channel signal transmission, a plurality of optical devices are arranged each at a predetermined distance as an array, and the distance between each of the optical devices is defined as 250 μm conforming to the inter-channel pitch of optical ribbon fibers used as a transmission medium of the optical signals.

However, when the optical devices and the integrated circuit are surface-mounted and electrically connected by bonding wires, the layout of the electrode pads formed to the integrated circuit is naturally restricted to the outer periphery of the surface to result in a problem that in the layout cannot cope with high pin count configuration (increase in the number of input/output electrode pads) along with enhancement in the functionality of the integrated circuit.

On the other hand, as an optical module conforming to the high pin count configuration of the integrated circuit, an optical module in which an integrated circuit and optical devices are flip-chip bonded over the multilayer substrate as shown in FIGS. 2, 3, and 4 has been known. In the state of mounting, electrode pads of the integrated circuit and electrode pads formed at the surface layer of the multilayer substrate are opposed to each other, respective electrode pads are electrically connected by solder bumps, and the optical devices and the integrated circuit are electrically connected by way of board conductors penetrating the board (conductive vias or through holes) formed in the multilayer substrate and an internal layer conductive lines. Internal layer signal lines of adjacent channels are formed in different layers respectively, a ground conductor or a power source conductor of a large area is disposed between each of the internal layer signal lines to suppress crosstalk between internal layer conductive lines adjacent to each other.

However, in a super high speed optical module at a signal transmission rate of 25 Gbps or higher, effect of crosstalk between signal conductive vias in the multilayer substrate on the signal quality is no more negligible. As means for suppressing the crosstalk between the signal conductive vias, a method of disposing a ground conductive via for crosstalk shielding between signal conductive vias in adjacent channels has been known. However, since the pitch between each of signal conductive vias connected to optical devices arranged in an array is at a pitch as narrow as 250 μm in the same manner as the pitch of array optical devices, it is difficult to provide the ground conductive via between the signal conductive vias.

### SUMMARY OF THE INVENTION

When optical devices and an integrated circuit are surface mounted and are electrically connected by way of bonding wires as in the optical module shown in FIG. 1, the layout of electrode pads formed to the integrated circuit is naturally restricted to the outer periphery of the surface and cannot cope with the high pin count configuration (increase in the number of input/output electrode pads) along with enhancement in the functionality of the integrated circuit.

On the other hand, when optical devices and an integrated circuit are connected electrically by way of conductive vias and internal layer conductive line formed in a multilayer substrate, since the distance between the conductive vias connected to the array optical devices is at a pitch as narrow as 250 μm, crosstalk between channels increases. Particularly, in high speed signal transmission at 25 Gbps or higher, effect of crosstalk between the conductive vias on the signal quality is no more negligible.

Then, the present invention intends to provide an optical module in which an integrated circuit is flip-chip mounted, and which can decrease crosstalk between adjacent channels even when super high speed transmission at 25 Gbps or higher is performed in an optical module, thereby attaining good signal transmission.

For overcoming the problem described above, a multilayer substrate and an optical module using the same according to the invention have the following main features.

In a first electrode pad and a second electrode pad adjacent to each other over a multilayer substrate, the first electrode pad is connected to a first conductive via and a first internal layer conductive line successively, while the second electrode pad is connected to a surface layer conductive line, a third electrode pad, a second conductive via, and a second internal conductive line successively. Aground conductive via or a power source conductive via is interposed between the first internal conductive line and the surface conductive line, and a formation layer in which a ground conductive line or a power source conductive line is formed is interposed between a first formation layer where the first internal layer conductive line is formed and a second formation layer where the second internal layer conductive line is formed.

The first electrode pad and the second electrode pad are connected with electrode pads formed on the surface of a first optical device and a second optical device. The first electrode pad and the second electrode pad may also be connected by way of bonding wires with the electrode pads formed on the surface of the first optical device and the second optical device.

When the optical module of the invention is used, an optical module capable of decreasing crosstalk between adjacent channels and attaining good signal transmission can be provided even when super high-speed transmission at 25 Gbps or higher is performed.

### BRIEF DESCRIPTION OF THE DRAWINGS

FIG. 1 is a schematic view of illustrating a conventional optical module;

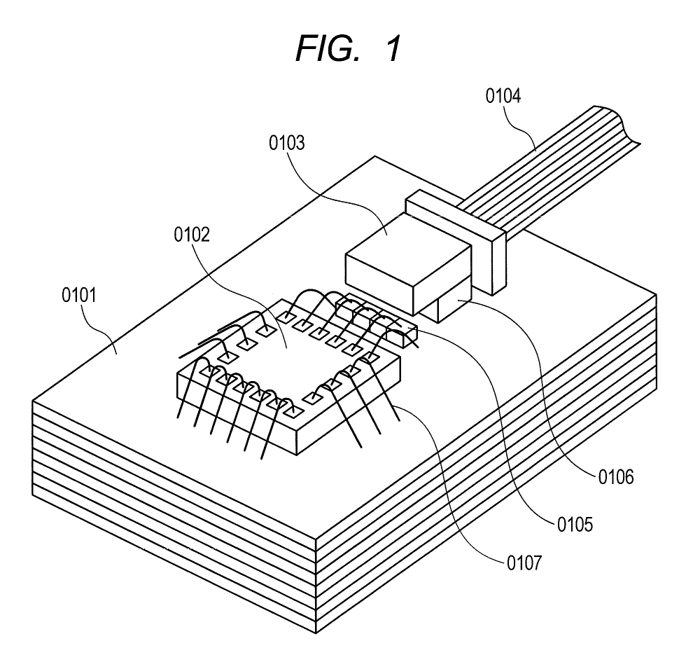

FIG. 2 is a schematic view of illustrating a conventional optical module;

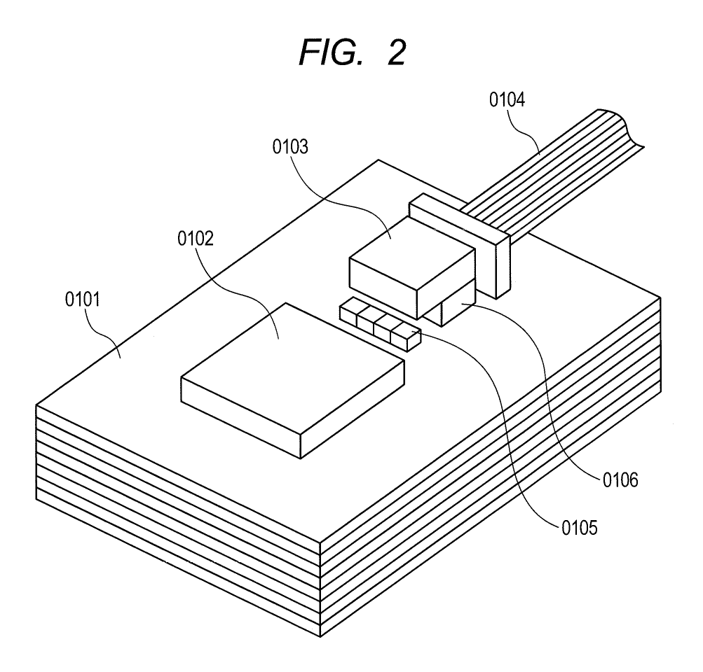

FIG. 3 is a view of illustrating signal lines to be connected with optical devices in a substrate that configures the conventional optical module;

FIG. 4 is a schematic cross sectional view of the conventional optical module;

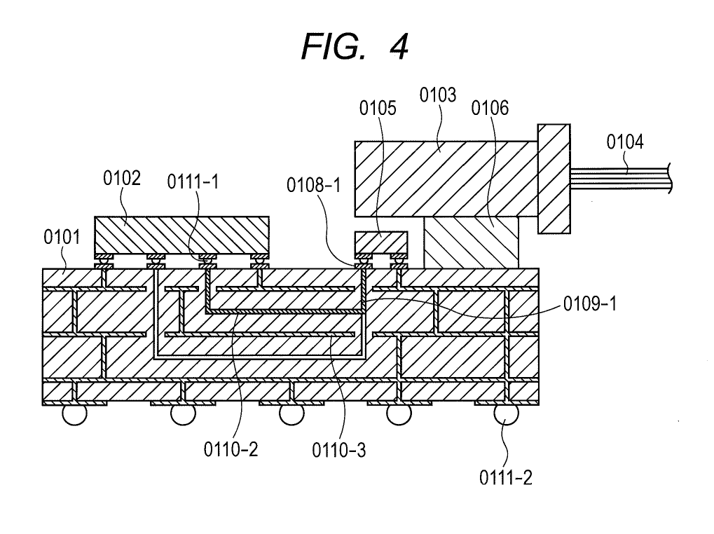

FIG. 5 is a schematic view of an optical module according to a first embodiment of the invention;

FIG. 6 is a schematic view of signal lines to be connected with optical devices of the first embodiment of the optical module according to the invention;

FIG. 7 is a cross sectional view of an optical module according to the first embodiment of the invention;

FIG. 8 is a graph showing crosstalk between adjacent channels of an optical module;

FIG. 9 is a schematic view of an optical module according to a second embodiment of the invention;

FIG. 10 is a top view of an optical module according to a third embodiment of the invention; and

FIG. 11 is a cross sectional view of an optical module according to the third embodiment of the invention.

### DETAILED DESCRIPTION OF THE PREFERRED EMBODIMENTS

Specific structures of preferred embodiments according to the present invention are to be described successively.

### First Embodiment

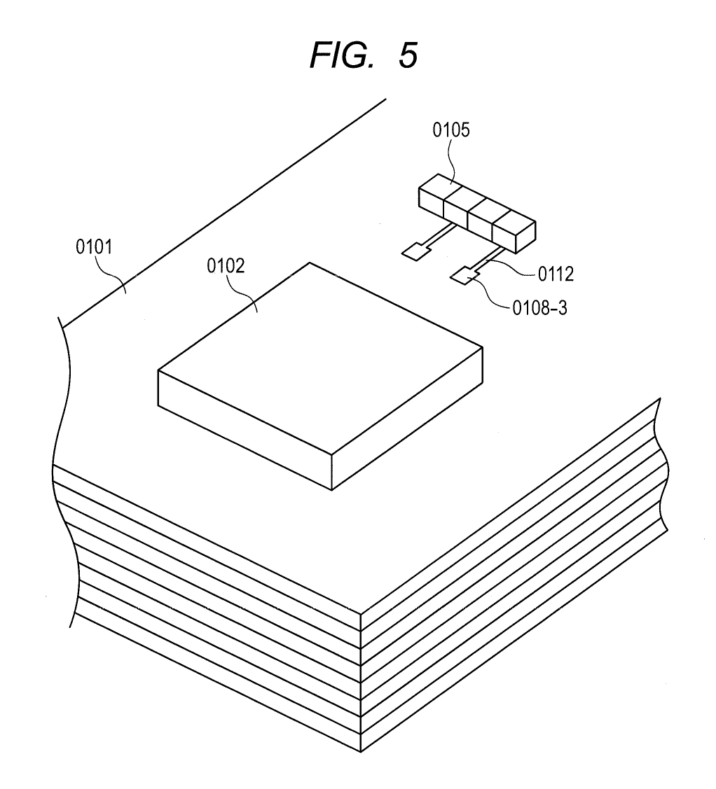

FIG. 5 shows a schematic view of an optical module according to a first embodiment of the invention. In this embodiment, optical devices 0105 and an integrated circuit 0102 are mounted respectively over a multilayer substrate 0101. Each of the optical devices 0105 is a semiconductor laser that converts electric signals into optical signals, or a photodiode that converts optical signals into electric signals. The integrated circuit 0102 is a driver circuit that performs waveform shaping and amplification of electric signals at the stage preceding to the semiconductor laser, or a transimpedance amplifier circuit for converting electric signals (current signals) inputted from the diode into voltage signals and then amplifying them. For attaining information transmission of large capacity, the optical devices 0105 are mounted in the form of an array and the distance between each of the optical devices is 250 μm conforming to the pitch between multi-channel optical fibers.

Surface layer conductive lines 0112 disposed over the multilayer substrate 0101 are led out as shown in the drawing from every other of plural optical devices 0105 arranged each at a predetermined pitch and connected to the electrode pads 0108-3. The surface layer conductive lines 0112 are to be described more specifically.

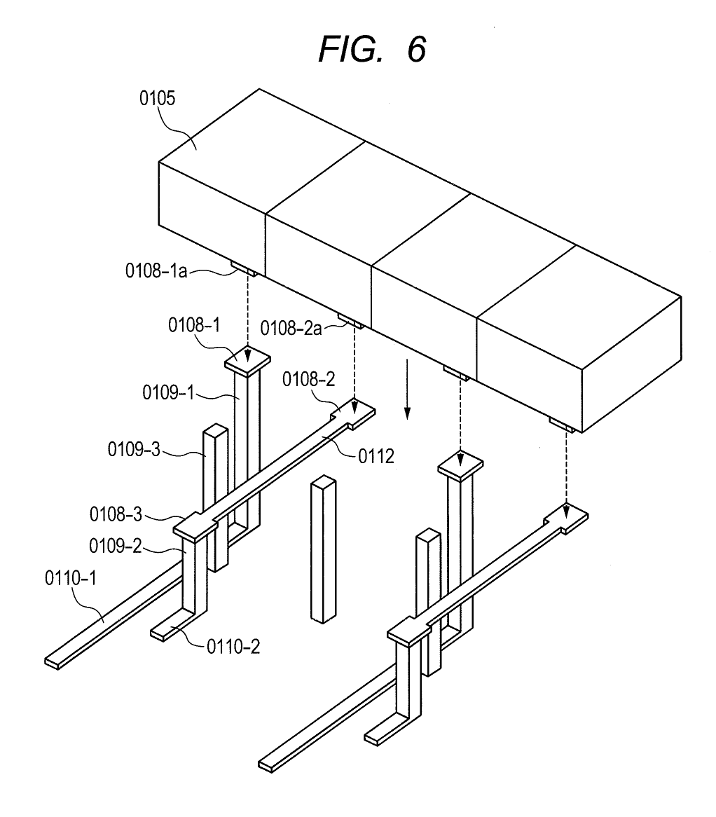

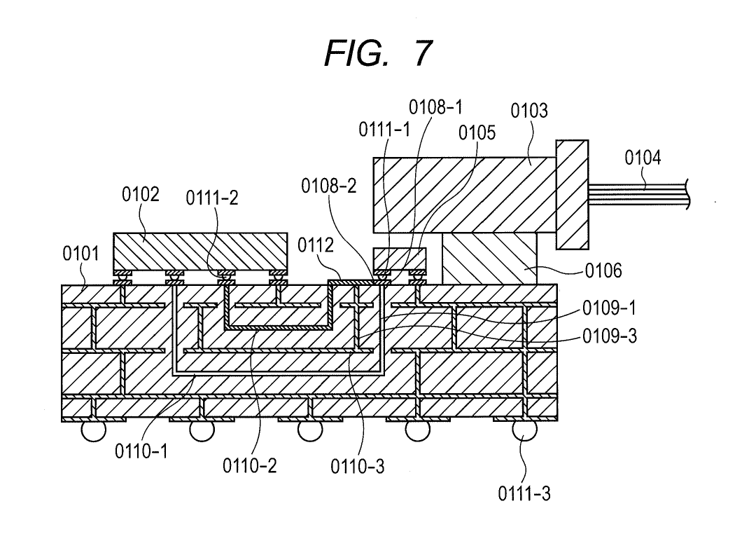

FIG. 6 shows a schematic view of interconnects near the optical devices 0105 in the optical module according to this embodiment, and FIG. 7 shows a cross sectional view of the optical module according to this embodiment.

At first, as shown in FIG. 7, an electrode pad 0108-1 is formed over the multilayer substrate 0101 and an electrode pad 0108-2 is formed adjacent to the electrode pad 0108-1 over the multilayer substrate 0101 in the same manner. In FIG. 7, the electrode pads 0108-1 and 0108-2 are illustrated being overlapped to each other.

An electrode pad 0108-1a formed to the optical device 0105 is disposed so as to oppose the electrode pad 0108-1 (refer to FIG. 6), and the respective electrode pads are electrically connected by a solder bump 0111-1. In the same manner, an electrode pad 0108-2a formed to the optical device 0105 is disposed so as to oppose the electrode pad 0108-2 (refer to FIG. 6) and the respective electrode pads are electrically connected by the solder bump 0111-1.

Electrode pads on the integrated circuit 0102 are also connected electrically with the electrode pads formed on the multilayer substrate 0101 by solder bumps 0111-2 in the same manner.

Then, a relation between the surface layer conductive line and the internal layer conductive line is to be described with reference to FIG. 6. For mainly illustrating the position of the lines, a solder bump connecting the electrode pad 0108-1 and the electrode pad 0108-1a is not shown. FIG. 6 shows line layers near the portion just below the electrode pad 0105 and other portions such as the multilayer substrate and the integrated circuit are not shown.

In the electrode pads 0108-1 and 0108-2 adjacent to each other formed over the multilayer substrate 0101, the electrode pad 0108-1 is connected with a conductive via 0109-1 disposed in a direction vertical to the multilayer substrate and an internal layer conductive line 0110-1 successively. Another electrode pad 0108-2 is connected with a surface layer conductive line 0112, an electrode pad 0108-3, a conductive via 0109-02, and an internal layer conductive line 0110-2 successively.

Usually, the internal layer conductive line 0110-1 or 0110-2 and the surface layer conductive line 0112 are disposed so as to extend in the longitudinal direction or disposed sometimes so as to round about in the midway, and they are arranged so as not to electrically short circuit to each other.

The conductive vias 0109-1, 0109-2, etc. are usually formed by burying a conductive material in a through hole penetrating a lamination film forming the multilayer substrate in a direction substantially vertical to the surface of the multilayer substrate.

The internal layer conductive lines 0110-1 and 0110-2 are formed along a plane substantially parallel to the surface of the multilayer substrate and situated at positions of depth from the surface of the substrate different from each other.

As a matter of fact, an electrically insulating layer or insulating film is formed between the internal layer conductive line 0110-1 and the internal layer conductive line 0110-2. Other conductive lines are also insulated in the direction vertical to the multilayer substrate in the same manner.

In FIG. 6, it can be seen that the distance between the conductive via 0109-1 and the conductive via 0109-2 is apparently larger than the distance between the electrode pads 0108-1 and 0108-2.

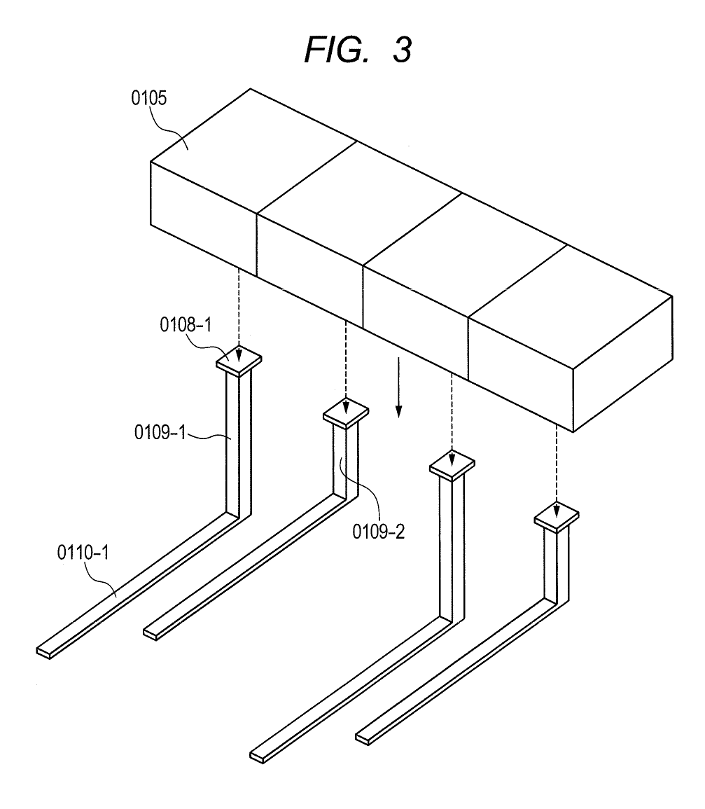

As shown in FIG. 3, the distance between the conductive via 0109-1 and the conductive via 0109-2 is identical with the distance between the electrode pads 0108-1 and 0108-2 in the conventional optical module. That is, the distance between the conductive vias 0109-1 and 0109-2 connected to the optical devices was at a pitch as narrow as 250 μm conforming to the pitch of the multi-channel optical fibers, and a conductive via for shielding crosstalk could not be disposed between the conductive via 0109-1 and the conductive via 0109-2 due to the problem in view of fabrication, etc. in the prior art

On the other hand, in this embodiment, the distance between the conductive via 0109-1 and the conductive via 0109-2 can be extended by additionally providing the surface layer conductive line 0112, and a conductive via 0190-3 for shielding crosstalk can be disposed between them. The conductive via 0109-3 is a ground conductive via or a power source conductive via.

“between the conductive via 0109-1 and the conductive via 0109-2” means that the shielding conductive via 0109-3 is disposed so as to be situated in a planar region put between a projection image of the line of the internal layer conductive line 0110-1 projected on the surface of the multi-layer substrate and the surface conductive lines 0112.

The internal layer conductive line 0110-3 of a large area is formed between the internal layer conductive lines 0110-1 and 0110-2 (refer to FIG. 7), to decrease crosstalk between the internal layer conductive lines 0110-1 and 0110-2. The internal layer conductive line 0110-3 is a ground conductive line or a power source conductive line.

Based on the structure of this embodiment, the conductive via 0109-3 for shielding crosstalk can be disposed between the conductive via 0109-1 and the conductive via 0109-2, so that crosstalk between the channels in the direction vertical to the substrate (crosstalk between the conductive vias to each other) can be decreased. Further, since the conductive line 0110-3 of the large area is formed between the internal layer conductive lines 0110-1 and 0110-2, crosstalk between the channels in the direction parallel to the board (crosstalk between the internal layer conductive lines to each other) can also be decreased.

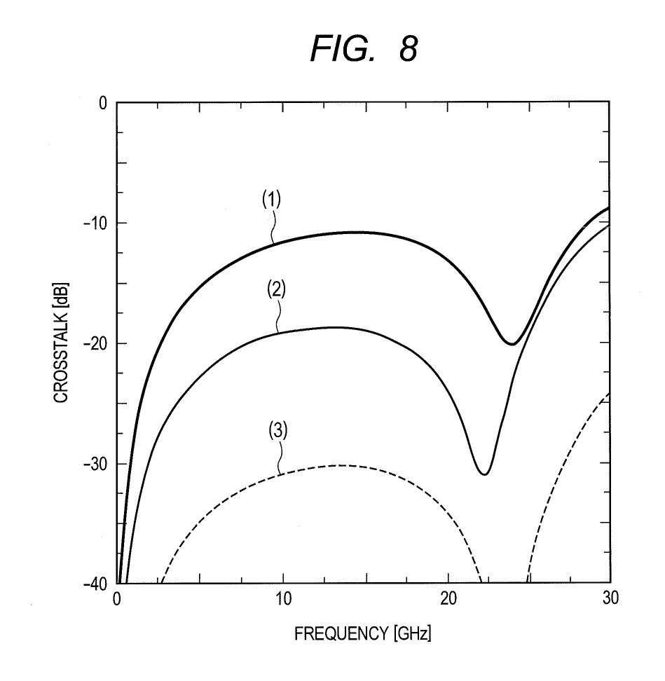

FIG. 8 shows the result of calculation for crosstalk between the conductive vias, in which the frequency is plotted on the abscissa and the amount of crosstalk is plotted on the ordinate. As the measuring conditions, the diameter of the conductive via is 100 μm and the length of the conductive via is 1.0 mm. As the board material, alumina (dielectric constant 10) was used as the material of the multilayer substrate for mounting the optical devices and tungsten was used as the conductor material. Among three groups shown in the drawing, plot (1) shows a case where the pitch between the conductive vias is 250 μm and no conductive via for shielding crosstalk is present between the conductive vias, the plot (2) shows a case where the pitch between the conductive vias is 500 μm and no conductive via for shielding crosstalk is present between the signal conductive vias, and the plot (3) shows a case where the pitch between the conductive vias is 500 μm, and the conductive via for shielding crosstalk is present between the conductive vias, respectively. For example, crosstalk at 12.5 GHz which is a fundamental frequency of 25 Gbps signal is −11 dB in the plot (1) corresponding to the conventional module, whereas the characteristic is improved as −30 dB in the plot (3) corresponding to the embodiment.

### Second Embodiment

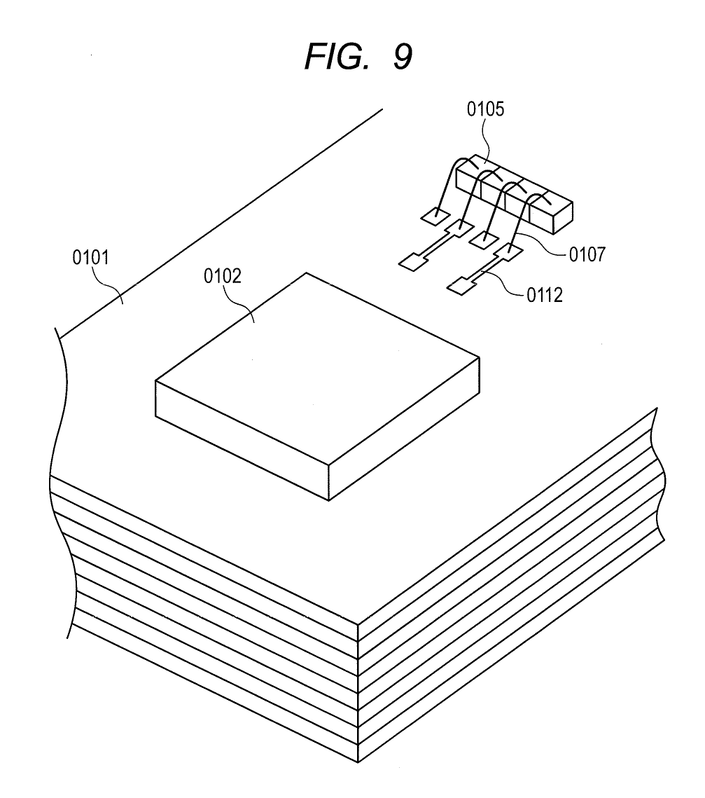

FIG. 9 shows a schematic view of an optical module according to a second embodiment of the invention. This embodiment is identical with the first embodiment except that the electrode pads of the optical devices 0105 and the electrode pads of the multilayer substrate 0101 are connected by bonding wires 0107. Accordingly, detailed description therefor is to be omitted.

Also in this structure, good characteristics decreased in the crosstalk can be obtained in the same manner as in the first embodiment.

This embodiment is applicable in a case where the electrode pads disposed to the optical devices 0105 cannot be faced down as shown in the first embodiment.

### Third Embodiment

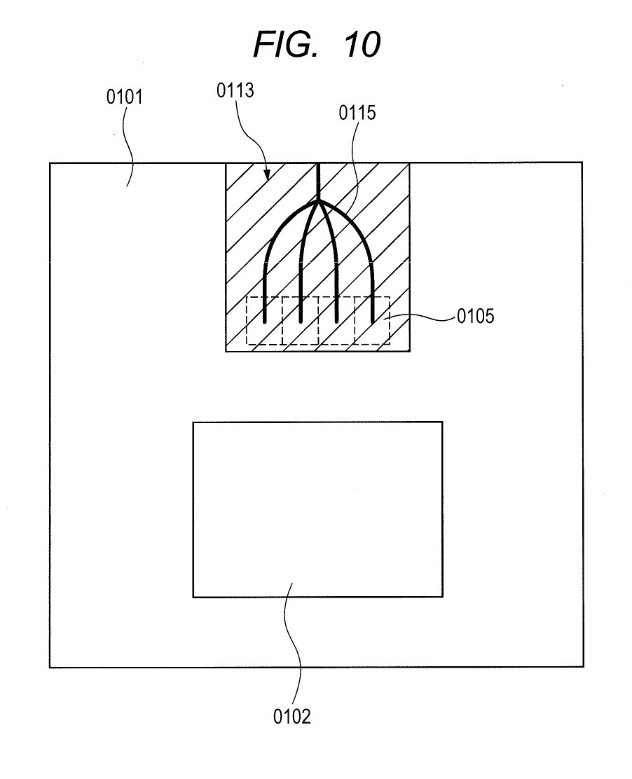

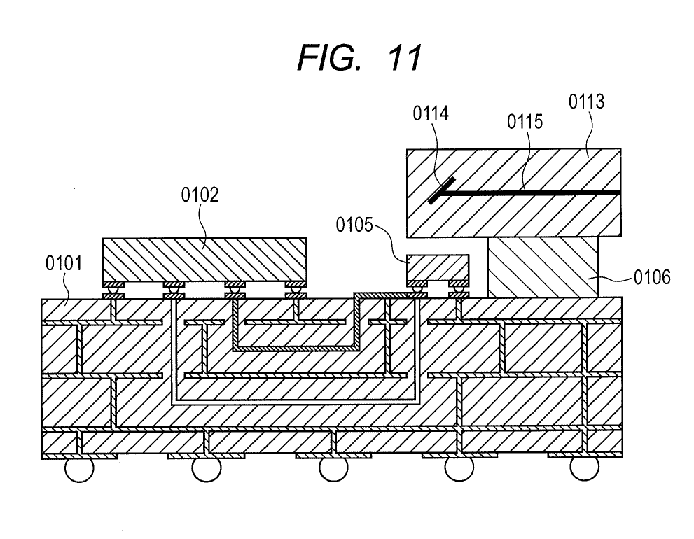

FIG. 10 shows an upper plan view of an optical module according to a third embodiment of the invention. FIG. 11 is a cross sectional view of the optical module of this embodiment. In this embodiment, an optical multiplexer for converting a plurality of optical signals into one multiplexed signal, or an optical demultiplexer for converting one multiple signal into a plurality of optical signals is mounted in the input/output direction of the optical signal of the optical devices 105. The optical path of the optical signals inputted/outputted to and from the optical devices 0105 in the direction perpendicular to the substrate is converted to the direction horizontal to the substrate by a mirror 0114 formed in the optical multiplexer/demultiplexer 0113 (refer to FIG. 11) and the optical signals propagate through an optical waveguide 0115 formed in the optical multiplexer/demultiplexer 0113. This embodiment is identical with the first embodiment except that the optical multiplexer/demultiplexer is mounted above the optical devices 0105.

Accordingly, good characteristics reduced in the crosstalk can be obtained from the optical multiplexer/demultiplexer.

What is claimed is:

1. A multilayer substrate including a lamination film in which internal layers having electroconductivity and insulation layers are laminated in plurality and conductive vias penetrating the lamination film for electrically connecting the internal layers to each other, the multilayer substrate comprising:
a first internal layer conductive line connected by way of a first conductive via to one of a plurality of electrode pads disposed over the multilayer substrate; and
a second internal layer conductive line connected by way of a second conductive via to other one of electrode pads adjacent to the one of the electrode pads,
wherein the other one of electrode pad and the second conductive via are connected by way of a surface conductive line disposed over the surface of the multilayer substrate, and
wherein a ground conductive via kept at a ground potential or a power source conductive via kept at a power source potential is disposed between the surface layer conductive line and the first internal layer conductive line.

2. The multilayer substrate according to claim 1, wherein
a ground conductive line layer kept at a ground potential or a power source conductive line layer kept at a power source potential is further disposed between the first internal layer conductive line and the second internal layer conductive line.

3. The multilayer substrate according to claim 1, wherein
the ground conductive via or the power source conductive via is disposed so as to be situated between a projection image formed by projecting the first internal layer conductive line onto the surface of the multilayer substrate and the surface layer conductive line.

4. The multilayer substrate according to claim 1, wherein
the second conductive via and the surface layer conductive line are connected by way of another electrode pad different from the one or other one of the electrode pad, and the ground conductive via or the power source conductive via is disposed so as to be situated between one of the electrode pads and another electrode pad.

5. The multilayer substrate according to claim 1, wherein
the surface layer conductive line is disposed such that the longitudinal direction thereof is along the longitudinal direction of the first and second internal layer conductive lines.

6. An optical module where at least an optical device and an electronic circuit device are mounted over a substrate, the optical module comprising:
a multilayer substrate having a lamination film where internal layers having electroconductivity and insulation layers are laminated in plurality, and conductive vias disposed penetrating the laminate film for electrically connecting the internal layer conductive line to each other;
a first internal layer conductive line connected by way of a first conductive via to one of a plurality of electrode pads disposed over the multilayer substrate;
a second conductive via connected by way of a surface layer conductive line disposed on the surface of the multilayer substrate to other one of electrode pads adjacent to the one of the electrode pads; and
a second internal layer conductive line connected by way of the second conductive via,
wherein a ground conductive via kept at a ground potential or a power source conductive via kept at a power source potential is disposed between the surface layer conductive line and the first internal layer conductive line,
wherein a ground conductive line layer kept at a ground potential or a power source conductive line layer kept at a power source potential is disposed between the first internal layer conductive line and the second internal layer conductive line, and
wherein each of the optical devices and the electronic circuit device are connected by way of the electrode pad disposed to each of them to one of the plurality of electrode pads disposed over the multilayer substrate.

7. The optical module according to claim 6, wherein
some of the electrode pads disposed to optical devices and a plurality of electrode pads arranged over the multilayer substrate are connected by way of bonding wires.

8. The optical module according to claim 6, wherein
a plurality of the optical devices are devices in an array arranged in an identical wafer.

9. The optical module according to claim 6, wherein
the optical device is a semiconductor laser in which an optical signal modulation system is a direct or indirect modulation system.

10. The optical module according to claim 6, wherein
the optical device is a semiconductor laser in which the direction of optical resonation is horizontal or vertical to a wafer.

11. The optical module according to claim 6, wherein
a light receiving/light emitting portion and a lens of the optical device are integrated.

12. The optical module according to claim 6, wherein
an external lens is mounted in the input/output direction of optical signals inputted/outputted from and to the optical device.

13. The optical module according to claim 6, wherein
the module has an optical multiplication portion for converting a plurality of optical signals into one multiple optical signal, or an optical demultiplication portion for converting one multiple optical signal into a plurality of optical signals in the input/output direction of optical signals inputted/outputted to and from the optical devices.
